(19) United States
(12) Patent Application Publication
(10) Pub. No.: US 2017/0047119 A1
(43) Pub. Date: Feb. 16, 2017

(54) Data Storage Method, Storage Apparatus, and Computing Device

(71) Applicant: Huawei Technologies Co., Ltd., Shenzhen (CN)

(72) Inventors: Jun Xu, Hangzhou (CN); Junfeng Zhao, Shenzhen (CN)

(21) Appl. No.: 15/337,710

(22) Filed: Oct. 28, 2016

Related U.S. Application Data
(63) Continuation of application No. PCT/CN2014/076553, filed on Apr. 30, 2014.

(51) Int. Cl. G11C 14/00; G11C 7/10; G06F 12/128

(52) U.S. Cl. CPC G11C 14/0045; G06F 12/128; G11C 14/009; G11C 7/1048; G06F 2212/69

(57) ABSTRACT

A data storage method, a storage apparatus and a computing device are disclosed. The method includes receiving a presetting command sent by a CPU, where the presetting command instructs to write 1 to a location, which corresponds to a cache line, in memory; writing, according to the presetting command, 1 to the location, which corresponds to the cache line, in the memory; receiving a write command sent by the CPU of writing data in the cache line to the memory; and writing, according to the write command, data 0 in the cache line to a location, which corresponds to the data 0, in the memory.

### CROSS-REFERENCE TO RELATED APPLICATIONS

This application is a continuation of International Application No. PCT/CN2014/076553, filed on Apr. 30, 2014, which is incorporated by reference in its entirety.

### TECHNICAL FIELD

The present disclosure relates to the field of information technologies, and in particular, to a data storage method, a storage apparatus, and a computing device.

### BACKGROUND

Phase change memory (PCM) has characteristics of short read and write delays and a long service life as a new-generation non-violate memory (NVM) medium. However, the write delay of the PCM is far greater than the read delay, and delays of the PCM at the time of writing 0 and writing 1 are asymmetric. During the time of writing 0 or performing resetting, the delay is excessively short, and during the time of writing 1 or performing setting, the delay is excessively long. The two delays differ from each other by a factor of more than ten times, and the read delay is the shortest. For the PCM, writing 0 and writing 1 are not distinguished in the prior art. Because of a limitation of the delay of writing 1, an access delay of a PCM page is relatively long.

### SUMMARY

Embodiments of the present disclosure provide a data storage method, a storage apparatus, and a computing device, which can reduce an access delay.

A first aspect provides a data storage method, including receiving a presetting command sent by a central processing unit (CPU), where the presetting command instructs to write 1 to a location, which corresponds to a cache line, in memory, writing, according to the presetting command, 1 to the location, which corresponds to the cache line, in the memory, receiving a write command sent by the CPU of writing data in the cache line to the memory, and writing, according to the write command, data 0 in the cache line to a location, which corresponds to the data 0 in the memory.

With reference to the first aspect, in a first possible implementation manner, the presetting command is generated by the CPU when the CPU sets a monitoring identifier of the cache line.

With reference to the first aspect or the first possible implementation manner of the first aspect, in a second possible implementation manner, before the writing, according to the write command, data 0 in the cache line to a location, which corresponds to the data 0, in the memory, the method further includes determining that the presetting command has been executed, or determining that the presetting command is being executed, and waiting for the presetting command to be completed.

With reference to the second possible implementation manner of the first aspect, in a third possible implementation manner, the method further includes removing the presetting command from the presetting command queue when the write command is received and the presetting command exists in a presetting command queue, and writing the data in the cache line to a location, which corresponds to the data in the cache line, in the memory.

With reference to the first aspect or any one of the first to the third possible implementation manners of the first aspect, in a fourth possible implementation manner, the writing, according to the presetting command, 1 to the location, which corresponds to the cache line, in the memory, includes determining, according to the presetting command, the location, which corresponds to the cache line in the memory, determining a location at which data is 0 in the location, which corresponds to the cache line, in the memory, and writing 1 to the location at which the data is 0.

With reference to the first aspect or any one of the first to the fourth possible implementation manners of the first aspect, in a fifth possible implementation manner, the memory is PCM or resistive random access memory (ReRAM).

A second aspect provides a data storage method, including sending a presetting command to a memory controller, where the presetting command instructs to write 1 to a location, which corresponds to a cache line, in memory, and sending a write command of writing data in the cache line to the memory to the memory controller, such that the memory controller writes, according to the write command, data 0 in the cache line to a location, which corresponds to the data 0, in the memory.

With reference to the second aspect, in a first possible implementation manner, before the sending a presetting command to a memory controller, the method further includes generating the presetting command when a monitoring identifier of the cache line is set.

With reference to the first possible implementation manner of the second aspect, in a second possible implementation manner, the generating the presetting command includes determining, according to tag information and index information of the cache line, a start address of the memory corresponding to the presetting command, and generating the presetting command according to the start address and a size of the cache line.

With reference to the second aspect or the first or the second possible implementation manner of the second aspect, in a third possible implementation manner, the memory is PCM or ReRAM.

A third aspect provides a memory controller, including a receiving module configured to receive a presetting command sent by a CPU, where the presetting command instructs to write 1 to a location, which corresponds to a cache line, in memory, a presetting module configured to write, according to the presetting command, 1 to the location, which corresponds to the cache line in the memory, the receiving module is further configured to receive a write command sent by the CPU of writing data in the cache line to the memory and a storage module configured to write, according to the write command, data 0 in the cache line to a location, which corresponds to the data 0 in the memory.

With reference to the third aspect, in a first possible implementation manner, the presetting command is generated by the CPU when the CPU sets a monitoring identifier of the cache line.

With reference to the third aspect or the first possible implementation manner of the third aspect, in a second possible implementation manner, the storage module is further configured to determine that the presetting command has been executed, or determine that the presetting command is being executed and wait for the presetting command to be completed before the data 0 in the cache line is written, according to the write command, to the location, which corresponds to the data 0, in the memory.

With reference to the second possible implementation manner of the third aspect, in a third possible implementation manner, the storage module is further configured to remove the presetting command from the presetting command queue, and write the data in the cache line to a location, which corresponds to the data in the cache line, in the memory when the receiving module receives the write command and the presetting command exists in a presetting command queue.

With reference to the third aspect or any one of the first to the third possible implementation manners of the third aspect, in a fourth possible implementation manner, the presetting module is further configured to determine, according to the presetting command, the location, which corresponds to the cache line, in the memory, determine a location at which data is 0 in the location, which corresponds to the cache line, in the memory, and write 1 to the location at which the data is 0.

With reference to the third aspect or any one of the first to fourth possible implementation manners of the third aspect, in a fifth possible implementation manner, the memory is PCM or ReRAM.

A fourth aspect provides a central processing unit CPU, including a generation module configured to generate a presetting command, where the presetting command instructs to write 1 to a location, which corresponds to a cache line, in memory, and a sending module configured to send the presetting command to a memory controller. The generation module is further configured to generate a write command of writing data in the cache line to the memory, and the sending module is further configured to send the write command to the memory controller, such that the memory controller writes, according to the write command, data 0 in the cache line to a location, which corresponds to the data 0 in the memory.

With reference to the fourth aspect, in a first possible implementation manner, the generation module is further configured to generate the presetting command when the receiving module receives the write command and the presetting command exists in a presetting command queue.

With reference to the fourth aspect or the first possible implementation manner of the fourth aspect, in a second possible implementation manner, the generation module is further configured to determine, according to tag information and index information of the cache line, a start address of the memory corresponding to the presetting command, and generate the presetting command according to the start address and a size of the cache line.

With reference to the fourth aspect or the first or the second possible implementation manner of the fourth aspect, in a third possible implementation manner, the memory is PCM or ReRAM.

Based on the foregoing technical solutions in the embodiments of the present disclosure, 1 is first written, according to a presetting command sent by a CPU, to a location, which corresponds to a cache line, in memory. After a write command sent by the CPU is received, data 0 in the cache line is written to a location, which corresponds to the data 0, in the memory in order to reduce an access delay.

### BRIEF DESCRIPTION OF DRAWINGS

To describe the technical solutions in the embodiments of the present disclosure more clearly, the following briefly describes the accompanying drawings required for describing the embodiments of the present disclosure. The accompanying drawings in the following description show merely some embodiments of the present disclosure.

FIG. 1 is a schematic diagram of an application scenario according to an embodiment of the present disclosure;

FIG. 2 is a schematic flowchart of a data storage method according to an embodiment of the present disclosure;

FIG. 3 is a schematic flowchart of a data storage method according to another embodiment of the present disclosure;

FIG. 4 is a schematic block diagram of a memory controller according to an embodiment of the present disclosure;

FIG. 5 is a schematic block diagram of a CPU according to an embodiment of the present disclosure; and

FIG. 6 is a schematic structural diagram of a data storage apparatus according to an embodiment of the present disclosure.

### DESCRIPTION OF EMBODIMENTS

The following clearly describes the technical solutions in the embodiments of the present disclosure with reference to the accompanying drawings in the embodiments of the present disclosure. The described embodiments are a part rather than all of the embodiments of the present disclosure.

It should be understood that technical solutions of the embodiments of the present disclosure may be applied to various storage media whose delay of writing 0 and a delay of writing 1 are asymmetric, for example, PCM and ReRAM. For convenience of description, description is made using the PCM as an example in the following embodiments.

In the embodiments of the present disclosure, a memory controller may be an independent device, or may be integrated in a CPU, which is not limited in the present disclosure.

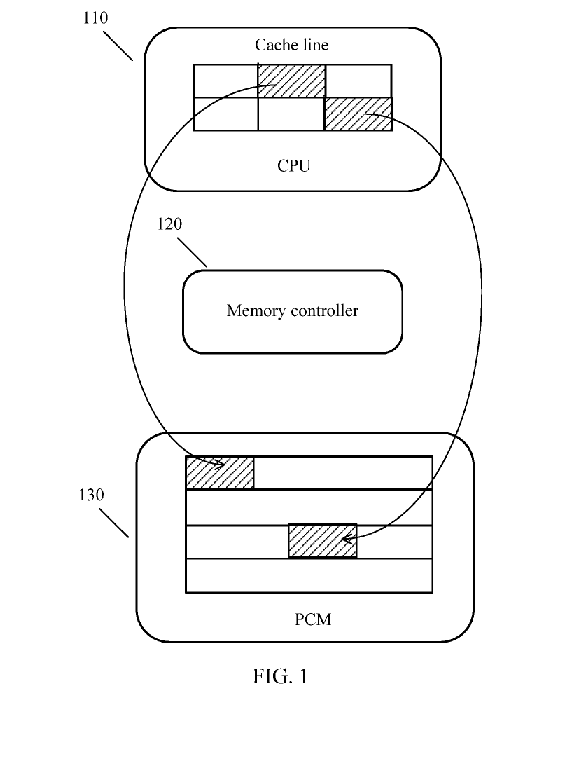

FIG. 1 is a schematic diagram of a scenario to which an embodiment of the present disclosure may be applied. In FIG. 1, PCM 130 is used as memory, and a CPU 110 accesses data in the PCM 130 using a memory controller 120. An access granularity is a cache line.

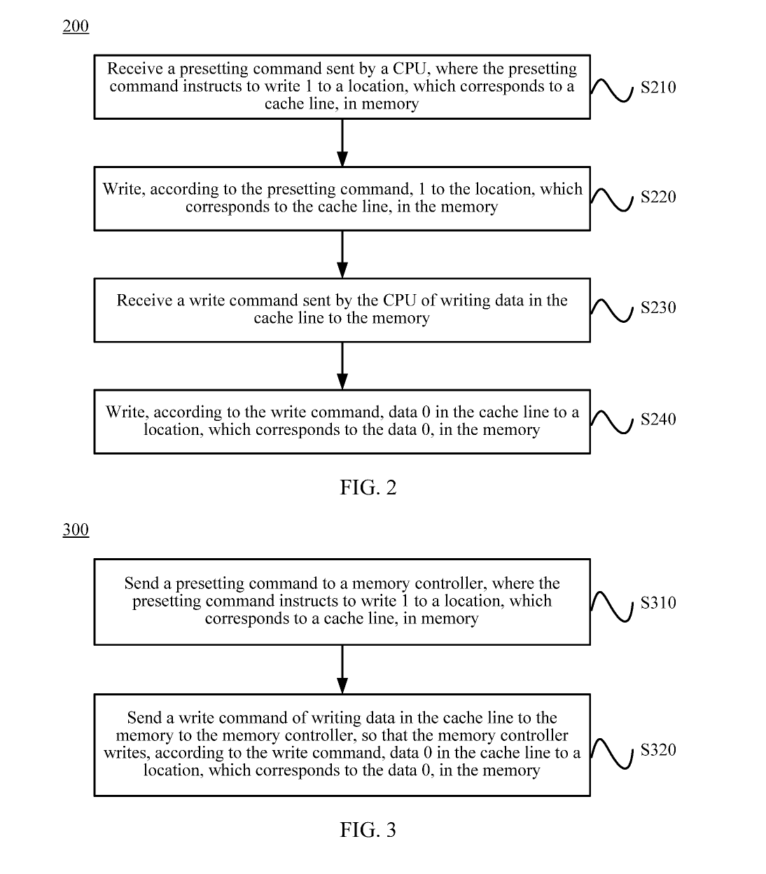

FIG. 2 shows a schematic flowchart of a data storage method 200 according to an embodiment of the present disclosure. The method 200 is performed by a memory controller (for example, the memory controller 120 in FIG. 1). As shown in FIG. 2, the method 200 includes the following steps.

Step S210: Receive a presetting command sent by a CPU, where the presetting command instructs to write 1 to a location, which corresponds to a cache line, in memory.

Step S220: Write, according to the presetting command, 1 to the location, which corresponds to the cache line, in the memory.

Step S230: Receive a write command sent by the CPU of writing data in the cache line to the memory.

Step S240: Write, according to the write command, data 0 in the cache line to a location, which corresponds to the data 0, in the memory.

In this embodiment of the present disclosure, before the data in the cache line is written (that is, written back) to the memory, the CPU first sends the presetting command to the memory controller and the presetting command instructs to write 1 to the location, which corresponds to the cache line, in the memory. After receiving the presetting command, the memory controller executes the presetting command to write 1 to the location, which corresponds to the cache line, in the memory. In an embodiment, the memory controller prefills, using the presetting command, 1 to all locations, which correspond to written-back cache lines, in the memory. When writing back the cache line, the CPU sends the write command of writing the data in the cache line to the memory to the memory controller. After receiving the write command, the memory controller writes the data 0 in the cache line to the location, which corresponds to the data 0, in the memory. In an embodiment, when executing the write command, the memory controller only needs to write data whose value is 0 to the corresponding location in the memory. In another embodiment, for data whose value is 1, since 1 is already at the corresponding location in the memory, there is no need to perform writing again. In other words, a write process is a process of selectively writing 0. In an embodiment, for a storage medium whose delay of writing 0 is smaller than a delay of writing 1, a write delay can be reduced.

Therefore, according to the data storage method of this embodiment of the present disclosure, 1 is first written, according to a presetting command sent by a CPU, to a location, which corresponds to a cache line, in memory. Thereafter, when a write command sent by the CPU is received, data 0 in the cache line is written to a location, which corresponds to the data 0, in the memory in order to reduce an access delay.

In this embodiment of the present disclosure, optionally, the presetting command is generated by the CPU when the CPU sets a monitoring identifier of the cache line. In other words, when the CPU sets the monitoring identifier of the cache line, the CPU may generate the presetting command.

For example, the monitoring identifier may be a dirty identifier when performing first dirty writing on the cache line because the CPU sets the dirty identifier, generates the presetting command, and sends the presetting command to the memory controller.

It should be understood that the presetting command may be generated at another moment, for example, before or after the monitoring identifier is set. Otherwise, the presetting command may not be related to setting of the monitoring identifier, which is not limited in the present disclosure.

The CPU determines, according to tag information and index information of the cache line, a start address of the memory corresponding to the presetting command, and generates the presetting command according to the start address and a size of the cache line. In other words, the presetting command includes a preset memory location, where the start address of the preset memory location is determined by the CPU according to the tag information and the index information of the cache line, and a size of the preset memory location is the size of the cache line.

After receiving the presetting command sent by the CPU, the memory controller writes, according to the presetting command, 1 to the location, which corresponds to the cache line, in the memory.

In this embodiment of the present disclosure, optionally, the writing, according to the presetting command, 1 to the location, which corresponds to the cache line, in the memory includes determining, according to the presetting command, the location, which corresponds to the cache line, in the memory, determining a location at which data is 0 in the location, which corresponds to the cache line, in the memory, and writing 1 to the location at which the data is 0.

After receiving the presetting command sent by the CPU, the memory controller parses the presetting command, determines the preset memory location, in other words, determines the location corresponds to the cache line, in the memory, then determines the location at which the data is 0 in these locations, and writes 1 to the location at which the data is 0. For example, the memory controller parses the presetting command, obtains a preset row and column address of the memory, reads data of the address to a buffer, determines a location at which a value is 0 in the buffer, and writes 1 to the location at which the value is 0. It should be understood that the location at which the value is 0 may not be determined in the location, which corresponds to the cache line, in the memory. Instead, 1 is written at all locations, which correspond to cache lines, in the memory, which may also fall within the protection scope of the present disclosure.

When writing back the cache line to the corresponding location in the memory, the CPU sends the write command of writing the data in the cache line to the memory to the memory controller. The memory controller writes, according to the write command, the data 0 in the cache line to the location, which corresponds to the data 0, in the memory. For example, the memory controller only needs to write the data whose value is 0 in the cache line to the corresponding location in the memory.

In this embodiment of the present disclosure, optionally, before the writing, according to the write command, data 0 in the cache line to a location, which corresponds to the data 0, in the memory, the method 200 further includes determining that the presetting command has been executed, or determining that the presetting command is being executed, and waiting for the presetting command to be completed.

The presetting command and the write command may be in conflict. For example, when the memory controller receives the write command, execution on the presetting command of a same address (e.g., a same cache line) is not finished or is not performed yet. Therefore, when determining that the presetting command has been executed, the memory controller may write the data 0 in the cache line to the location, which corresponds to the data 0, in the memory. Alternatively, when determining that the presetting command is being executed, may wait for the presetting command to be completed, and then write the data 0 in the cache line to the location, which corresponds to the data 0, in the memory.

For a case in which the presetting command is not executed yet, that is, when the write command is received, the presetting command of the same cache line exists in a presetting command queue, the presetting command may be removed from the presetting command queue, and then the data in the cache line is written to a location, which corresponds to the data in the cache line, in the memory.

Therefore, optionally, in an embodiment of the present disclosure, the method 200 may further include removing the presetting command from the presetting command queue when the write command is received, if the presetting command exists in a presetting command queue, and writing the data in the cache line to a location, which corresponds to the data in the cache line, in the memory.

Optionally, when the presetting command is being executed, the presetting command to be completed may not be waited for. Alternatively, a presetting operation is cancelled, meaning that executing the presetting command is stopped, and then the data in the cache line is written to the location, which corresponds to the data in the cache line, in the memory.

By means of the data storage method of this embodiment of the present disclosure, for a storage medium whose delay of writing 0 is smaller than a delay of writing 1, a write delay can be reduced in order to reach a level of a dynamic random access memory (DRAM) such that PCM or the like can be used to replace the DRAM to serve as main memory.

It should be understood that the technical solution of this embodiment of the present disclosure is further applicable to a scenario in which the storage medium of which the delay of writing 0 is smaller than the delay of writing 1 is mixed with the DRAM, for example, a scenario of a hybrid memory in a manner of using the DRAM and the PCM as a scratchpad. For the hybrid memory in the manner of using the DRAM and the PCM as the scratchPad, it may be determined, according to a tag of a cache line, whether the cache line corresponds to the PCM or the DRAM. If the cache line corresponds to the PCM, the technical solution of this embodiment of the present disclosure may be used, for example, delivering the presetting command when first dirty writing is performed.

The data storage method according to this embodiment of the present disclosure is described above in detail from the perspective of the memory controller, and a data storage method according to an embodiment of the present disclosure is described below in detail from the perspective of a CPU.

FIG. 3 shows a schematic flowchart of a data storage method 300 according to an embodiment of the present disclosure. The method 300 is performed by a CPU (for example, the CPU 110 in FIG. 1). As shown in FIG. 3, the method 300 includes the following steps.

Step S310: Send a presetting command to a memory controller, where the presetting command instructs to write 1 to a location, which corresponds to a cache line, in memory.

Step S320: Send a write command of writing data in the cache line to the memory to the memory controller such that the memory controller writes, according to the write command, data 0 in the cache line to a location, which corresponds to the data 0, in the memory.

In this embodiment of the present disclosure, before the data in the cache line is written (e.g., written back) to the memory, the CPU first sends the presetting command to the memory controller, where the presetting command instructs to write 1 to the location, which corresponds to the cache line, in the memory. After receiving the presetting command, the memory controller executes the presetting command, to write 1 to the location, which corresponds to the cache line, in the memory and to prefill, using the presetting command, 1 to all locations, which correspond to written-back cache lines, in the memory. When the cache line is written back, the CPU sends the write command of writing the data in the cache line to the memory to the memory controller. After receiving the write command, the memory controller writes the data 0 in the cache line to the location, which corresponds to the data 0, in the memory. For example, when executing the write command, the memory controller only needs to write data whose value is 0 to the corresponding location in the memory. For data whose value is 1, because 1 is already at the corresponding location in the memory, there is no need to perform writing again. In an embodiment, a write process is a process of selectively writing 0. For a storage medium whose delay of writing 0 is smaller than a delay of writing 1, a write delay can be reduced.

Therefore, according to the data storage method of an embodiment of the present disclosure, a presetting command is first sent to a memory controller such that the memory controller writes 1 to a location, which corresponds to a cache line, in memory, and then a write command is sent to the memory controller, such that the memory controller writes data 0 in the cache line to a location, which corresponds to the data 0, in the memory in order to reduce an access delay.

In this embodiment of the present disclosure, optionally, before the sending a presetting command to a memory controller, the method 300 further includes generating the presetting command when a monitoring identifier of the cache line is set.

For example, the monitoring identifier may be a dirty identifier. When performing first dirty writing on the cache line, the CPU sets the dirty identifier, generates the presetting command, and sends the presetting command to the memory controller.

In this embodiment of the present disclosure, optionally, the generating the presetting command includes determining, according to tag information and index information of the cache line, a start address of the memory corresponding to the presetting command, and generating the presetting command according to the start address and a size of the cache line.

For example, the presetting command includes a preset memory location, where the start address of the preset memory location is determined by the CPU according to the tag information and the index information of the cache line, and a size of the preset memory location is the size of the cache line.

After generating the presetting command, the CPU sends the presetting command to the memory controller. The memory controller writes, according to the presetting command, 1 to the location, which corresponds to the cache line, in the memory. For detailed description, refer to the description in the embodiment on foregoing memory controller side. Details are not described herein again.

When writing back the cache line to the corresponding location in the memory, the CPU sends the write command of writing the data in the cache line to the memory to the memory controller. The memory controller writes, according to the write command, the data 0 in the cache line to the location, which corresponds to the data 0, in the memory. In other words, the memory controller only needs to write the data whose value is 0 in the cache line to the corresponding location in the memory.

It should be understood that in this embodiment of the present disclosure, interaction between the memory controller and the CPU that is described on the memory controller side, related characteristics, functions, and the like correspond to the description on the CPU side. Details are not described herein again for brevity.

By means of the data storage method of this embodiment of the present disclosure, for a storage medium whose delay of writing 0 is smaller than a delay of writing 1, a write delay can be reduced in order to reach a level of a DRAM, such that PCM or the like can be used to replace the DRAM to serve as main memory.

It should be understood that sequence numbers of the foregoing processes do not mean execution sequences in the embodiments of the present disclosure. The execution sequences of the processes should be determined according to functions and internal logic of the processes, and should not be construed as any limitation on the implementation processes of the embodiments of the present disclosure.

A data storage method according to an embodiment of the present disclosure is described above in detail, and a memory controller and a CPU according to embodiments of the present disclosure are described below.

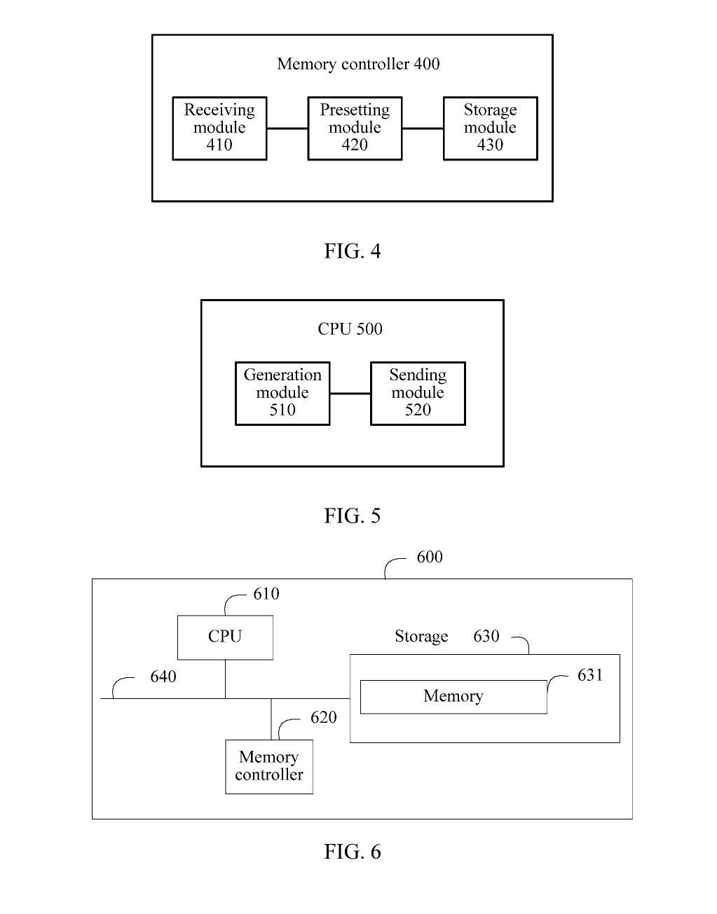

FIG. 4 shows a schematic block diagram of a memory controller 400 according to an embodiment of the present disclosure. As shown in FIG. 4, the memory controller 400 includes a receiving module 410 configured to receive a presetting command sent by a CPU, where the presetting command instructs to write 1 to a location, which corresponds to a cache line, in memory, a presetting module 420 configured to write, according to the presetting command, 1 to the location, which corresponds to the cache line, in the memory, where the receiving module 410 is further configured to receive a write command sent by the CPU of writing data in the cache line to the memory, and a storage module 430 configured to write, according to the write command, data 0 in the cache line to a location, which corresponds to the data 0, in the memory.

In this embodiment of the present disclosure, before the data in the cache line is written (e.g., written back) to the memory, the CPU first sends the presetting command to the memory controller, where the presetting command instructs to write 1 to the location, which corresponds to the cache line, in the memory. After the receiving module 410 of the memory controller 400 receives the presetting command, the presetting module 420 executes the presetting command, to write 1 to the location, which corresponds to the cache line, in the memory, and to prefill, using the presetting command, 1 to all locations, which correspond to written-back cache lines, in the memory. When the cache line is written back, the CPU sends the write command of writing the data in the cache line to the memory to the memory controller. After the receiving module 410 receives the write command, the storage module 430 writes the data 0 in the cache line to the location, which corresponds to the data 0, in the memory. For instance, when executing the write command, the memory controller only needs to write data whose value is 0 to the corresponding location in the memory. For data whose value is 1, because 1 is already at the corresponding location in the memory, there is no need to perform writing again. In an embodiment, a write process is a process of selectively writing 0. For a storage medium whose delay of writing 0 is smaller than a delay of writing 1, a write delay can be reduced.

Therefore, according to the memory controller of this embodiment of the present disclosure, 1 is first written, according to a presetting command sent by a CPU, to a location, which corresponds to a cache line, in memory, and then when a write command sent by the CPU is received, data 0 in the cache line is written to a location, which corresponds to the data 0, in the memory in order to reduce an access delay.

In this embodiment of the present disclosure, optionally, the presetting command is generated by the CPU when the CPU sets a monitoring identifier of the cache line.

In this embodiment of the present disclosure, optionally, the storage module 430 is further configured to before the data 0 in the cache line is written, according to the write command, to the location, which corresponds to the data 0, in the memory, determine that the presetting command has been executed, or determine that the presetting command is being executed, and wait for the presetting command to be completed.

In this embodiment of the present disclosure, optionally, the storage module 430 is further configured to when the receiving module 410 receives the write command, and when the presetting command exists in a presetting command queue, remove the presetting command from the presetting command queue, and write the data in the cache line to a location, which corresponds to the data in the cache line, in the memory.

In this embodiment of the present disclosure, optionally, the presetting module 420 is further configured to determine, according to the presetting command, the location, which corresponds to the cache line, in the memory, determine a location at which data is 0 in the location, which corresponds to the cache line, in the memory, and write 1 to the location at which the data is 0.

In this embodiment of the present disclosure, optionally, the memory is PCM or ReRAM.

The memory controller 400 according to this embodiment of the present disclosure may correspond to the memory controller in the data storage method according to the embodiment of the present disclosure, and the foregoing and other operations and/or functions of the modules in the memory controller 400 are separately performed to implement corresponding procedures of the foregoing methods. Details are not described herein again for brevity.

By means of the memory controller of this embodiment of the present disclosure, for a storage medium whose delay of writing 0 is smaller than a delay of writing 1, a write delay can be reduced, to reach a level of a DRAM, such that PCM or the like can be used to replace the DRAM to serve as main memory.

FIG. 5 shows a schematic block diagram of a CPU 500 according to an embodiment of the present disclosure. As shown in FIG. 5, the CPU 500 includes a generation module 510 configured to generate a presetting command, where the presetting command instructs to write 1 to a location, which corresponds to a cache line, in memory, a sending module 520 configured to send the presetting command to a memory controller, where the generation module 510 is further configured to generate a write command of writing data in the cache line to the memory, and the sending module 520 is further configured to send the write command to the memory controller, such that the memory controller writes, according to the write command, data 0 in the cache line to a location, which corresponds to the data 0, in the memory.

In this embodiment of the present disclosure, before the data in the cache line is written (e.g., written back) to the memory, the generation module 510 of the CPU 500 generates the presetting command, where the presetting command instructs to write 1 to the location, which corresponds to the cache line, in the memory. The sending module 520 sends the presetting command to the memory controller. After receiving the presetting command, the memory controller executes the presetting command, to write 1 to the location, which corresponds to the cache line, in the memory, and to prefill, using the presetting command, 1 to all locations, which correspond to written-back cache lines, in the memory. When the cache line is written back, the generation module 510 generates the write command of writing the data in the cache line to the memory, and the sending module 520 sends the write command to the memory controller. After receiving the write command, the memory controller writes the data 0 in the cache line to the location, which corresponds to the data 0, in the memory. For example, when executing the write command, the memory controller only needs to write data whose value is 0 to the corresponding location in the memory. For data whose value is 1, because 1 is already at the corresponding location in the memory, there is no need to perform writing again. In an embodiment, a write process is a process of selectively writing 0. For a storage medium whose delay of writing 0 is smaller than a delay of writing 1, a write delay can be reduced.

Therefore, according to the CPU of this embodiment of the present disclosure, a presetting command is first sent to a memory controller, such that the memory controller writes 1 to a location, which corresponds to a cache line, in memory, and then a write command is sent to the memory controller, such that the memory controller writes data 0 in the cache line to a location, which corresponds to the data 0, in the memory in order to reduce an access delay.

In this embodiment of the present disclosure, optionally, the generation module 510 is further configured to generate the presetting command when a monitoring identifier of the cache line is set.

In this embodiment of the present disclosure, optionally, the generation module 510 is further configured to determine, according to tag information and index information of the cache line, a start address of the memory corresponding to the presetting command, and generate the presetting command according to the start address and a size of the cache line.

In this embodiment of the present disclosure, optionally, the memory is PCM or ReRAM.

The CPU 500 according to this embodiment of the present disclosure may correspond to the CPU in the data storage method according to the embodiment of the present disclosure, and the foregoing and other operations and/or functions of the modules in the CPU 500 are separately performed to implement corresponding procedures of the foregoing methods. Details are not described herein again for brevity.

By means of the CPU of this embodiment of the present disclosure, for a storage medium whose delay of writing 0 is smaller than a delay of writing 1, a write delay can be reduced, to reach a level of a DRAM, such that PCM or the like can be used to replace the DRAM to serve as main memory.

FIG. 6 shows a schematic structural diagram of a data storage apparatus 600 according to still another embodiment of the present disclosure. The data storage apparatus 600 includes a CPU 610, a memory controller 620, a storage 630, and a bus 640. The bus 640 is configured to implement connection and communication between these components. The memory controller 620 may be integrated in the CPU 610. The storage 630 includes memory 631, where the memory 631 is a storage medium whose delay of writing 0 and a delay of writing 1 are asymmetric, for example, PCM. The CPU 610 includes a cache, where the cache includes at least one cache line.

The CPU 610 is configured to send a presetting command to the memory controller 620, where the presetting command instructs to write 1 to a location, which corresponds to a cache line, in the memory 631.

The memory controller 620 is configured to receive the presetting command sent by the CPU 610, and write, according to the presetting command, 1 to the location, which corresponds to the cache line, in the memory 631.

The CPU 610 is further configured to send a write command of writing data in the cache line to the memory 631 to the memory controller 620.

The memory controller 620 is further configured to receive the write command sent by the CPU 610, and write, according to the write command, data 0 in the cache line to a location, which corresponds to the data 0, in the memory 631.

Optionally, the CPU 610 is configured to generate the presetting command when a monitoring identifier of the cache line is set.

Optionally, the CPU 610 is configured to determine, according to tag information and index information of the cache line, a start address of the memory corresponding to the presetting command, and generate the presetting command according to the start address and a size of the cache line.

Optionally, the memory controller 620 is configured to determine that the presetting command has been executed, or determine that the presetting command is being executed and wait for the presetting command to be completed before the data 0 in the cache line is written, according to the write command, to the location, which corresponds to the data 0, in the memory.

Optionally, the memory controller 620 is configured to, when the write command is received and when the presetting command exists in a presetting command queue, remove the presetting command from the presetting command queue, and write the data in the cache line to a location, which corresponds to the data in the cache line, in the memory.

Optionally, the memory controller 620 is configured to determine, according to the presetting command, the location, which corresponds to the cache line, in the memory, determine a location at which data is 0 in the location, which corresponds to the cache line, in the memory, and write 1 to the location at which the data is 0.

As can be seen from the foregoing technical solutions provided in the embodiments of the present disclosure, in the embodiments of the present disclosure, 1 is first written to a location, which corresponds to a cache line, in memory, and then data 0 in the cache line is written to a location, which corresponds to the data 0, in the memory in order to reduce an access delay.

It should be understood that, the term “and/or” in this embodiment of the present disclosure describes only an association relationship for describing associated objects and represents that three relationships may exist. For example, A and/or B may represent the following three cases: Only A exists, both A and B exist, and only B exists. In addition, the character “/” in this specification generally indicates an “or” relationship between the associated objects.

A person of ordinary skill in the art may be aware that, in combination with the examples described in the embodiments disclosed in this specification, units and algorithm steps may be implemented by electronic hardware, computer software, or a combination thereof. To clearly describe the interchangeability between the hardware and the software, the foregoing has generally described compositions and steps of each example according to functions. Whether the functions are performed by hardware or software depends on particular applications and design constraint conditions of the technical solutions. A person skilled in the art may use different methods to implement the described functions for each particular application, but it should not be considered that the implementation goes beyond the scope of the present disclosure.

It may be clearly understood by a person skilled in the art that, for the purpose of convenient and brief description, for a detailed working process of the foregoing system, apparatus, and unit, reference may be made to a corresponding process in the foregoing method embodiments, and details are not described herein again.

In the several embodiments provided in the present application, it should be understood that the disclosed system, apparatus, and method may be implemented in other manners. For example, the described apparatus embodiment is merely exemplary. For example, the unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may or may not be physically separate, and parts displayed as units may or may not be physical units, may be located in one position, or may be distributed on a plurality of network units. A part or all of the units may be selected according to actual needs to achieve the objectives of the solutions of the embodiments of the present disclosure.

In addition, functional units in the embodiments of the present disclosure may be integrated into one processing unit, or each of the units may exist alone physically, or two or more units are integrated into one unit. The integrated unit may be implemented in a form of hardware, or may be implemented in a form of a software functional unit.

When the integrated unit is implemented in the form of a software functional unit and sold or used as an independent product, the integrated unit may be stored in a computer-readable storage medium. Based on such an understanding, the technical solutions of the present disclosure essentially, or the part contributing to the prior art, or all or a part of the technical solutions may be implemented in the form of a software product. The software product is stored in a storage medium and includes several instructions for instructing a computer device (which may be a personal computer, a server, or a network device) to perform all or a part of the steps of the methods described in the embodiments of the present disclosure. The foregoing storage medium includes: any medium that can store program code, such as a universal serial bus (USB) flash drive, a removable hard disk, a read-only memory (ROM), a random access memory (RAM), a magnetic disk, or an optical disc.

The foregoing descriptions are merely specific embodiments of the present disclosure, but are not intended to limit the protection scope of the present disclosure.

What is claimed is:

1. A data storage method applied in a computing device including a memory controller and a processor coupled to the memory controller, the method comprising:
receiving, by the memory controller, a first presetting command sent by the processor to instruct the memory controller to write 1 to a first location, which corresponds to a first cache line, in a memory of the computing device;
writing, by the memory controller according to the first presetting command, 1 to the first location, which corresponds to the first cache line, in the memory;
receiving, by the memory controller, a first write command sent by the processor for instructing the memory controller to write a first data in the first cache line to the memory; and
writing, by the memory controller according to the first write command, data 0 in the first cache line to a second location, which corresponds to the data 0 in the first cache line, in the memory.

2. The method according to claim 1, wherein the first presetting command is generated by the processor when the processor sets a monitoring identifier of the first cache line.

3. The method according to claim 1, wherein writing, by the memory controller according to the first write command, data 0 in the first cache line to the second location, which corresponds to the data 0 in the first cache line, in the memory occurs after the first presetting command has been executed.

4. The method according to claim 1, wherein writing 1 to the first location in the memory comprises:
determining, by the memory controller according to a first start address and a size of the first cache line in the first presetting command, the first location in the memory; and
writing, by the memory controller, 1 to a third location at which the data is 0 in the first location of the memory.

5. The method according to claim 3, further comprising:
receiving, by the memory controller, a second write command sent by the processor for instructing the memory controller to write a second data in a second cache line to the memory;
removing, by the memory controller, a second presetting command from a presetting command queue when the second presetting command has not been executed, wherein the second presetting command is configured to instruct the memory controller to write 1 to a fourth location, which corresponds to the second cache line, in the memory; and
writing, by the memory controller, the second data in the second cache line to a fifth location, which corresponds to the second data in the second cache line, in the memory.

6. The method according to claim 1, wherein the memory is phase change memory (PCM) or resistive random access memory (ReRAM).

7. A data storage method applied in a computing device including a memory controller and a processor coupled to the memory controller, the method comprising:
sending, by the processor, a first presetting command to the memory controller to instruct the memory controller to write 1 to a first location, which corresponds to a first cache line, in a memory of the computing device;
writing, by the memory controller according to the first presetting command, 1 to the first location, which corresponds to the first cache line, in the memory;
sending, by the processor, a first write command for instructing the memory controller to write a first data in the first cache line to the memory to the memory controller; and
writing, by the memory controller according to the first write command, data 0 in the first cache line to a second location, which corresponds to the data 0 in the first cache line, in the memory.

8. The method according to claim 7, further comprising generating, by the processor, the first presetting command when the processor sets a monitoring identifier of the first cache line.

9. The method according to claim 7, wherein the first presetting command comprises a first start address and a size of the first cache line, and wherein writing 1 to the first location in the memory comprises:
determining, by the memory controller according to the first start address and the size of the first cache line in the first presetting command, the first location in the memory; and
writing, by the memory controller, 1 to a third location at which the data is 0 in the first location of the memory.

10. The method according to claim 7, further comprising:
receiving, by the memory controller, a second write command sent by the processor for instructing the memory controller to write a second data in a second cache line to the memory;
removing, by the memory controller, a second presetting command from a presetting command queue when the second presetting command has not been executed, wherein the second presetting command instructs the memory controller to write 1 to a fourth location, which corresponds to the second cache line, in the memory; and
writing, by the memory controller, the second data in the second cache line to a fifth location, which corresponds to the second data in the second cache line, in the memory.

11. The method according to claim 7, wherein the memory is phase change memory (PCM) or resistive random access memory (ReRAM).

12. A storage apparatus comprising:
a memory; and
a memory controller coupled to the memory and configured to:
receive a first presetting command to instruct the memory controller to write 1 to a first location, which corresponds to a first cache line, in the memory of the computing device;
write, according to the first presetting command, 1 to the first location, which corresponds to the first cache line, in the memory;
receive a first write command for instructing the memory controller to write a first data in the first cache line to the memory; and
write, according to the first write command, data 0 in the first cache line to a second location, which corresponds to the data 0 in the first cache line, in the memory.

13. The storage apparatus according to claim 12, wherein writing data 0 in the first cache line to the second location comprises writing, according to the first write command, data 0 in the first cache line to the second location, which corresponds to the data 0 in the first cache line, in the memory after the first presetting command has been executed.

14. The storage apparatus according to claim 12, wherein writing 1 to the first location in the memory comprises the memory controller configured to:
determine, according to a first start address and a size of the first cache line in the first presetting command, the first location in the memory; and
write 1 to a third location at which the data is 0 in the first location of the memory.

15. The storage apparatus according to claim 12, wherein the memory controller is further configured to:
receive a second write command for instructing the memory controller to write a second data in a second cache line to the memory;
remove a second presetting command from a presetting command queue when the second presetting command has not been executed, wherein the second presetting command instructs the memory controller to write 1 to a fourth location, which corresponds to the second cache line, in the memory; and
write the second data in the second cache line to a fifth location, which corresponds to the second data in the second cache line, in the memory.

16. The storage apparatus according to claim 12, wherein the memory is phase change memory (PCM) or resistive random access memory (ReRAM).

17. A computing device, comprising:
a processor configured to send a first presetting command to a memory controller coupled to the processor, wherein the first presetting command instructs the memory controller to write 1 to a first location, which corresponds to a first cache line, in a memory of the computing device,
wherein the memory controller is configured to write, according to the first presetting command, 1 to the first location, which corresponds to the first cache line, in the memory,
wherein the processor is further configured to send a first write command for instructing the memory controller to write a first data in the first cache line to the memory to the memory controller, and
wherein the memory controller is further configured to write, according to the first write command, data 0 in the first cache line to a second location, which corresponds to the data 0 in the first cache line, in the memory.

18. The computing device according to claim 17, wherein the processor is further configured to generate the first presetting command when the processor sets a monitoring identifier of the first cache line.

19. The computing device according to claim 17, wherein the first presetting command comprises a first start address and a size of the first cache line, and wherein the memory controller is configured to:
determine, according to the first start address and the size of the first cache line in the first presetting command, the first location in the memory; and
write 1 to a third location at which the data is 0 in the first location of the memory.

20. The computing device according to claim 17, wherein the memory controller is further configured to:
receive a second write command sent by the processor for instructing the memory controller to write a second data in a second cache line to the memory;
remove a second presetting command from a presetting command queue when the second presetting command has not been executed, wherein the second presetting command instructs the memory controller to write 1 to a fourth location, which corresponds to the second cache line, in the memory; and
write the second data in the second cache line to a fifth location, which corresponds to the second data in the second cache line, in the memory.

21. The computing device according to claim 17, wherein the memory is phase change memory (PCM) or resistive random access memory (ReRAM).
